(19) United States
(12) Patent Application Publication
(10) Pub. No.: US 2025/0253409 A1
(43) Pub. Date: Aug. 7, 2025

(54) MANUFACTURING METHOD FOR SOLID-STATE BATTERY

(71) Applicant: TOYOTA JIDOSHA KABUSHIKI KAISHA, Toyota-shi (JP)

(72) Inventors: Ryo ASAKURA, Shizuoka-ken (JP); Shinya Shiotani, Nagoya-shi (JP); Sakina Kaneko, Fujisawa-shi (JP)

(73) Assignee: TOYOTA JIDOSHA KABUSHIKI KAISHA, Toyota-shi (JP)

(21) Appl. No.: 18/966,582

(22) Filed: Dec. 3, 2024

(30) Foreign Application Priority Data
Feb. 2, 2024 (JP) 2024-014615

(51) Int. Cl. H01M 10/0585; C23C 14/18; C23C 14/34; H01M 10/052; H01M 10/42

(52) U.S. Cl. CPC H01M 10/0585; C23C 14/18; C23C 14/34; H01M 10/052; H01M 10/4235

(57) ABSTRACT

A manufacturing method of a solid-state battery comprising a cathode layer, an anode layer, and a solid electrolyte layer disposed between the cathode layer and the anode layer and that also uses a deposition-dissolution reaction of metal lithium, wherein one surface of the solid electrolyte layer is a film forming face, and a protective layer having Li ion conductivity is formed on the film forming face. A step of obtaining a laminate in which the anode layer, the protective layer, and the cathode layer are laminated in this order after the film forming step, and pressing the laminate. The protective layer is formed so that an area of the protective layer is smaller than an area of the solid electrolyte layer when the laminate is viewed from the anode layer side.

### CROSS-REFERENCE TO RELATED APPLICATION

This application claims priority to Japanese Patent Application No. 2024-014615 filed on Feb. 2, 2024, incorporated herein by reference in its entirety.

### BACKGROUND

### 1. Technical Field

The present disclosure relates to a manufacturing method of a solid-state battery.

### 2. Description of Related Art

Various types of technology have been proposed regarding solid-state batteries such as disclosed in WO 2013/141241 and Japanese Unexamined Patent Application Publication No. 2023-149739 (JP 2023-149739 A).

### SUMMARY

WO 2013/141241 discloses coating a protective layer, selected from Li and metals which can be alloyed with Li, onto an anode layer side of a solid-state electrolyte layer by a gas-phase process. When performing coating with the protective layer, the protective layer may wrap around to the cathode layer, via side faces of the solid electrolyte layer, causing a solid-state battery to be short-circuited.

The present disclosure has been made in view of the above circumstances, and an object thereof is to provide a manufacturing method of a solid-state battery, in which short-circuiting can be suppressed.

That is to say, the present disclosure includes the following aspects.

<1> A manufacturing method of a solid-state battery that includes a cathode layer, an anode layer, and a solid electrolyte layer disposed between the cathode layer and the anode layer, and that also uses a deposition-dissolution reaction of metal lithium, includes film forming of a protective layer with Li-ionic conductivity on a film forming face of the solid electrolyte layer, in which one face of the solid electrolyte layer is the film forming face, and following the film forming, laminating the anode layer, the protective layer, the solid electrolyte layer, and the cathode layer, to obtain a laminate that is laminated in this order, and pressing the laminate, in which in the film forming, the protective layer is formed on the film forming face such that an area of the protective layer is smaller than an area of the solid electrolyte layer, when viewing the laminate from a side of the anode layer in plan view.

<2> The manufacturing method according to <1>, in which, in the film forming, the solid electrolyte layer extends outward from all outer edges of the protective layer when viewing the laminate from the side of the anode layer in plan view.

<3> The manufacturing method according to <1> or <2>, in which, in the film forming, the protective layer is formed on the film forming face by sputtering.

<4> The manufacturing method according to any one of <1> to <3>, in which the protective layer includes at least one of an In element and a Sn element.

<5> A manufacturing method of a solid-state battery that includes a cathode layer, an anode layer, and a solid electrolyte layer disposed between the cathode layer and the anode layer, and that also uses a deposition-dissolution reaction of metal lithium, includes
film forming of a protective layer with Li-ionic conductivity on a film forming face of the solid electrolyte layer, in which one face of the solid electrolyte layer is the film forming face, and
following the film forming, laminating the anode layer, the protective layer, the solid electrolyte layer, and the cathode layer, to obtain a laminate that is laminated in this order, and pressing the laminate, in which
the solid electrolyte layer includes a first solid electrolyte layer and a second solid electrolyte layer, and
in the film forming, one face of the first solid electrolyte layer is taken as the film forming face and the protective layer is formed on the film forming face, following which the second solid electrolyte layer is laminated on a face of the first solid electrolyte layer opposite to the film forming face, and pressed, to obtain the solid electrolyte layer.

According to the present disclosure, a manufacturing method of a solid-state battery, in which short-circuiting can be suppressed, can be provided.

### BRIEF DESCRIPTION OF THE DRAWINGS

Features, advantages, and technical and industrial significance of exemplary embodiments of the disclosure will be described below with reference to the accompanying drawings, in which like signs denote like elements, and wherein:

FIG. 1 is a schematic cross-sectional view showing a part of a solid-state battery of Example 1;

FIG. 2 is a schematic cross-sectional view showing a part of the solid-state battery of Example 2;

FIG. 3A is a schematic cross-sectional view illustrating a part of a solid-state battery according to a third embodiment;

FIG. 3B is a schematic plan view showing a part of the solid-state battery of the third embodiment; and

FIG. 4 is a schematic cross-sectional view showing a part of the solid-state battery of Comparative Example 1.

### DETAILED DESCRIPTION OF EMBODIMENTS

Hereinafter, embodiments according to the present disclosure will be described. Note that matters other than those specifically mentioned in the present specification and necessary for the implementation of the present disclosure (for example, a general configuration and a manufacturing process of a solid-state battery that does not characterize the present disclosure) can be understood as design matters of a person skilled in the art based on the prior art in the field. The present disclosure can be carried out based on content disclosed in the present specification and common knowledge in the technical field.

In the present disclosure, unless otherwise specified, the mean particle diameter of the particles is a value of the median diameter (D50) which is the particle diameter at an integrated value of 50% in a volume-based particle size distribution measured by laser diffraction/scattering particle size distribution measurement.

### 1. First Embodiment

In the present disclosure, a manufacturing method a solid-state battery includes a cathode layer, an anode layer, and a solid electrolyte layer disposed between the cathode layer and the anode layer, and using a deposition-dissolution reaction of metal lithium is provided.
film forming of a protective layer with Li-ionic conductivity on a film forming face of the solid electrolyte layer, in which one face of the solid electrolyte layer is the film forming face, and
following the film forming, laminating the anode layer, the protective layer, the solid electrolyte layer, and the cathode layer, to obtain a laminate that is laminated in this order, and pressing the laminate, in which

In the film forming step, the protective layer is formed on the film forming face so that an area of the protective layer is smaller than an area of the solid electrolyte layer in a plan view of the laminate from the anode layer side.

Examples of a method for improving the energy density of a solid-state battery include the application of a lithium-based active material such as metallic lithium, and the elimination of an anode without an anode layer during fabrication. In this case, as a method for improving the cycling characteristics and the rate characteristics of the solid-state batteries, a protective layer of a metal such as Sn between the anode layer and the solid electrolyte layer is introduced toward the solid electrolyte layer. However, when the protective layer is introduced, the protective layer adheres to the peripheral portion of the solid electrolyte layer or the cathode side of the solid electrolyte layer, and the solid-state battery may be short-circuited due to contact with the cathode terminal or the like.

As a measure for preventing a short circuit when a protective layer is introduced into a solid-state battery, a cathode peripheral edge protection is performed by an insulating member such as a polymer insulator film, but in the present disclosure, a protective layer having a size smaller than that of the solid electrolyte layer is disposed on the anode side of the solid electrolyte layer.

When the protective layer has a size smaller than that of the solid electrolyte layer, adhesion of the protective layer to the peripheral portion of the solid electrolyte layer or the cathode side of the solid electrolyte layer is prevented, and a short circuit of the solid-state battery at the time of introduction of the protective layer is suppressed.

According to the present disclosure, it is possible to suppress a short circuit of the solid-state battery caused by the protective layer being circuited from the side surface of the solid electrolyte layer and reaching the cathode layer during the step of forming the protective layer. In addition, an insulating member is not required, and the configuration of the solid-state battery is simplified.

The solid-state battery of the present disclosure includes a cathode including a cathode layer, an anode including an anode layer, and a solid electrolyte layer disposed between the cathode layer and the anode layer, and utilizes a deposition-dissolution reaction of metal lithium. The solid-state battery of the present disclosure has a protective layer between an anode layer and a solid electrolyte layer.

In the present disclosure, a solid-state battery means a battery including a solid electrolyte. The solid-state battery may be a semi-solid-state battery that is a solid-state battery including a solid electrolyte and a liquid-based material, or may be an all-solid-state battery that is a solid-state battery that does not include a liquid-based material.

When the set of the cathode, the solid electrolyte layer, and the anode is used as the power generation unit, the solid-state battery may have only one power generation unit or two or more power generation units. When the solid-state battery has two or more power generation units, the power generation units may be connected in series or in parallel.

When the solid-state battery is viewed from the cathode layer side in plan view, the area of the cathode layer may be smaller than or the same as the area of the solid electrolyte layer. When the solid-state battery is viewed from the anode layer side in plan view, the area of the protective layer is smaller than the area of the solid electrolyte layer. This eliminates the need for an insulator for preventing a short circuit at the periphery of the cathode.

When the aspect ratio is different as in the case where the shape of the solid-state battery in plan view is a rectangle, the solid electrolyte layer may extend from the outer edge of the protective layer toward the outside of the protective layer only in the region of the side where the cathode terminal is present.

When the solid-state battery is viewed from the anode layer side in plan view, the area of the anode layer may be smaller than the area of the solid electrolyte layer, may be smaller than the area of the protective layer, or may be the same.

The area of the cathode layer and the area of the anode layer may be the same or different, and from the viewpoint of suppressing the deposition of Li metallic dendrites, the area of the cathode layer may be smaller than the area of the anode layer.

When the solid-state battery is viewed from the cathode layer side in plan view, the solid electrolyte layer may extend outward from all outer edges of the cathode layer.

When the solid-state battery is viewed from the anode layer side in plan view, the solid electrolyte layer may extend outward from all outer edges of the protective layer.

When the solid-state battery is viewed from the anode layer side in plan view, the protective layer may extend outward from all outer edges of the anode layer.

When the solid-state battery is viewed from the anode layer side in plan view, the solid electrolyte layer may extend outward from all outer edges of the anode layer.

The solid-state battery includes an exterior body that houses a cathode layer, an anode layer, a solid electrolyte layer, and the like, if necessary.

The material of the exterior body is not particularly limited as long as it is stable in the solid electrolyte, and examples thereof include metals such as aluminum, polypropylene, polyethylene, and resins such as acrylic resin.

As the shape of the solid-state battery, for example, coin-type, laminate-type, cylindrical, and square-type, and the like.

The solid-state battery may be a primary battery or a secondary battery. Applications of solid-state batteries include, for example, power supplies for vehicles such as hybrid electric vehicle (HEV), plug-in hybrid electric vehicle (PHEV), battery electric vehicle (BEV), gasoline-powered vehicles, and diesel-powered vehicles. Among them, it may be used as a power source for driving hybrid electric vehicle (HEV), plug-in hybrid electric vehicle (PHEV), or battery electric vehicle (BEV). Further, the solid-state battery may be used as a power source for a moving object (for example, a railway, a ship, an aircraft, or the like) other than the vehicle, or may be used as a power source for an electric product such as an information processing apparatus.

### Protective Layer

It is sufficient that the protective layer contains a metal having Li ionic conductivity. Examples of the metal having Li ionic conductivity include Sn, In, Mg, Ag, Si, Ga, Zn, Sb, Bi, and Al. An alloy containing two or more of these metals may be used, or an alloy of one or more of these metals and Li may be used. At least one of In element and Sn element may be included.

The shape of the protective layer may be any shape as long as the area of the protective layer is smaller than the area of the solid electrolyte layer. The protective layer may have a hole therein in plan view. The shape and number of the holes are not particularly limited. The thickness of the protective layer may be 0.1 μm or more and 1 μm or less.

### Cathode

The cathode includes a cathode layer. The cathode optionally includes a cathode current collector.

### Cathode Layer

The cathode layer contains a cathode active material, and may contain a solid electrolyte, a conductive material, a binder, and the like, if necessary.

Examples of the cathode active material include elemental sulfur, sulfur and carbon, sulfur mixture with phosphorus, lithium, and the like, lithium nickel cobalt aluminum oxide (NCA), LiCoO₂, LiNiₓCo₁₋ₓO₂ (0<x<1), LiNi_{1/3}Co_{1/3}Mn_{1/3}O₂, LiMnO₂, LiMn₂O₄, LiNiO₂, LiVO₂, heterogeneous element-substituted Li—Mn spinel, lithium titanate, lithium metal phosphate, LiCoN, Li₂SiO₃, Li₄SiO₄. Examples of heterogeneous element-substituted Li—Mn spinel include LiMn_{1.5}Ni_{0.5}O₄, LiMn_{1.5}Al_{0.5}O₄, LiMn_{1.5}Mg_{0.5}O₄, LiMn_{1.5}Co_{0.5}O₄, LiMn_{1.5}Fe_{0.5}O₄, and LiMn_{1.5}Zn_{0.5}O₄. Examples of lithium titanate include Li₄Ti₅O₁₂. Examples of lithium metal phosphate includes LiFePO₄, LiMnPO₄, LiCoPO₄, and LiNiPO₄.

The shape of the cathode active material is not particularly limited, but may be particulate (cathode active material particles). The mean particle diameter of the cathode active material particles is not particularly limited, and may be 100 μm from 1 nm.

Coating layers including a Li ion-conductive compound may be formed on the cathode active material. This is because the reaction between the cathode active material and the solid electrolyte can be suppressed.

Examples of Li ion-conductive compound include LiNbO₃, Li₄Ti₅O₁₂, and Li₃PO₄. The thickness of the coating layers is, for example, 0.1 nm or more, and may be 1 nm or more. On the other hand, the thickness of the coating layers may be, for example, less than or equal to 100 nm and less than or equal to 20 nm. The coating ratio of the coating layer on the surface of the cathode active material is, for example, 70% or more, and may be 90% or more.

As the conductive material, a known material can be used, and examples thereof include carbon materials and metal particles. Examples of the carbon material include acetylene black (AB), furnace black, VGCF, carbon nanotubes, and carbon nanofibers. Among the above, from the viewpoint of electron conductivity, at least one selected from the group consisting of VGCF, a carbon nanotube, and a carbon nanofiber may be used. Examples of metal particles include particles of Ni, Cu, Fe, and SUS.

The content of the conductive material in the cathode layer is not particularly limited.

Examples of the solid electrolytes include a sulfide solid electrolyte, an oxide solid electrolytes, a hydride solid electrolyte, a halide solid electrolyte, an inorganic solid electrolyte such as a nitride solid electrolyte, and an organic polymer electrolyte such as a polymer electrolyte. From the viewpoint of suppressing the separation of the cathode layer and the anode layer from the solid electrolyte layer and further reducing the resistance of the solid-state battery, a relatively soft sulfide solid electrolyte may be used as the solid electrolyte. Only one type of solid electrolyte may be used alone, or two or more types of solid electrolyte may be used in combination.

Examples of the sulfide solid electrolyte include a solid electrolyte containing an Li element, an A element, and an S element. The A Element is at least one of P, As, Sb, Si, Ge, Sn, B, Al, Ga, and In. The sulfide solid electrolyte may further contain at least one of an O element and a halogen element. Examples of the halogen element (X) include an F element, a Cl element, a Br element, and an I elements. The sulfide solid electrolyte may be glass (amorphous), glass ceramics, or crystalline. When the sulfide solid electrolyte is a crystalline, the sulfide solid electrolyte has a crystalline phase. Examples of the crystalline phase include a Thio-LISICON crystalline phase, a LGPS crystalline phase, and an aldilodite crystalline phase. Examples of the sulfide solid electrolyte include Li₂S—P₂S₅, LiI—Li₂S—P₂S₅, LiI—LiBr—Li₂S—P₂S₅, Li₂S—SiS₂, Li₂S—GeS₂, and Li₂S—P₂S₅—GeS₂. Note that the description of “Li₂S—P₂S₅” means a material made of a raw material composition containing Li₂S and P₂S₅, and the same applies to other descriptions. The molar ratio of each element in the sulfide solid electrolyte can be controlled by adjusting the content of each element in the raw material. In addition, the molar ratio and the composition of the respective elements in the sulfide solid-state electrolyte can be measured, for example, by ICP emission spectrometry.

Examples of the oxide solid electrolyte include a solid electrolyte containing an Li element, a Z element (Z is at least one of Nb, B, Al, Si, P, Ti, Zr, Mo, W, and S), and an O element. Examples of the oxide solid electrolyte include Li₂O—B₂O₃—P₂O₅, Li₂O—SiO₂, Li₂O—B₂O₃, Li_{1.3}Al_{0.3}Ti_{0.7}(PO₄)₃, Li₅La₃Ta₂O₁₂, Li₇La₃Zr₂O₁₂, Li₆BaLa₂Ta₂O₁₂, Li_{3.6}Si_{0.6}P_{0.4}O₄, Li₄SiO₄, Li₃PO₄, and Li₃₊ₓPO₄₋ₓNₓ (1<x<3).

The hydride solid electrolyte has, for example, Li and hydrogen-containing complex anions. Examples of the complex anion include (BH₄)⁻, (NH₂)⁻, (AlH₄)⁻, and (AlH₆)₃.

Examples of the halogenated solid electrolyte include LiF, LiCl, LiBr, LiI, and LiI—Al₂O₃. Examples of the nitrided solid electrolyte include Li₃N.

The solid electrolyte may be solid electrolyte particles.

The mean particle diameter (D50) of the solid-electrolyte particles is not particularly limited, but may be 0.1 μm or more and 100 μm or less.

The content of the solid electrolyte in the cathode layer is not particularly limited, but may be, for example, within a range of 1% by mass to 80% by mass, where the total mass of the cathode layer is 100% by mass.

Examples of the binder include a rubber-based binder and a fluoride-based binder. Examples of the rubber-based binder include butadiene rubber, hydrogenated butadiene rubber, styrene butadiene rubber (SBR), hydrogenated styrene butadiene rubber, nitrile butadiene rubber, hydrogenated nitrile butadiene rubber, acrylonitrile butadiene rubber (ABR), and ethylene propylene rubber. Examples of the fluoride-based binder include polyvinylidene fluoride (PVDF), polyvinylidene fluoride-polyhexafluoropropylene copolymer (PVDF-HFP), polytetrafluoroethylene, and fluororubber.

The content of the binder in the cathode layer is not particularly limited.

The thickness of the cathode layer is not particularly limited.

The cathode layer can be formed by a conventionally known method.

For example, a cathode slurry is prepared by charging a cathode active material and, if necessary, other components into a solvent and stirring, and the cathode slurry is coated on one surface of a support such as a cathode current collector and dried to obtain a cathode layer.

Examples of the solvents include butyl acetate, butyl butyrate, heptane, and N-methyl-2-pyrrolidone.

A method of applying the cathode slurry on one surface of a support such as a cathode current collector is not particularly limited, and examples thereof include a doctor blade method, a metal mask printing method, an electrostatic coating method, a dip coating method, a spray coating method, a roll coating method, a gravure coating method, and a screen printing method.

As the support body, a support body with self-supporting properties can be appropriately selected and used, and there is no particular limitation. For example, metal foils such as Cu and Al can be used.

### Cathode Current Collector

As the cathode current collector, a known metal that can be used as a current collector of a solid-state battery can be used. As the metals above, a metal material containing one or more elements selected from the group consisting of Cu, Ni, Al, V, Au, Pt, Mg, Fe, Ti, Co, Cr, Zn, Ge, and In can be exemplified. Examples of cathode current collectors include SUS, aluminum, nickel, iron, titanium, and carbon.

The shape of the cathode current collector is not particularly limited, and various shapes such as a foil shape and a mesh shape can be used.

An anode, comprising:

The anode includes an anode layer. The anode optionally includes an anode current collector.

### Anode Layer

The anode layer may be present at least at the time of charging, may not be present at the time of manufacturing and at the time of complete discharge, or may be present.

The anode layer includes an anode active material. The anode layer may optionally contain at least one of a solid electrolyte, a conductive material, and a binder.

The anode layers may include, for example, a lithium-based active material, a carbon-based active material, an oxide-based active material, and a Si based active material as anode active materials.

Examples of the lithium-based active material include metallic lithium and lithium alloys. Examples of the metal element other than lithium included in the lithium alloy include Mg, Ag, In, Sn, Si, Ga, Au, and Pt.

Examples of the carbon-based active material include graphite, hard carbon, and soft carbon. Examples of the oxide-based active material include lithium titanate.

Examples of Si active material include elemental Si, Si alloy, and silicon oxide.

Examples of the shape of the anode active material include particulate. The mean particle diameter of the anode active material particles is not particularly limited, and may be 100 μm from 1 nm.

Examples of the conductive material, the solid electrolyte, and the binder used in the anode layer include the same materials as those exemplified as the conductive material, the solid electrolyte, and the binder that can be included in the cathode layer.

The thickness of the anode layer may be 0.1 μm or more and may be 100 μm or less.

### Anode Current Collector

The material of the anode current collector may be a material that does not alloy with Li, and may be, for example, SUS, copper, and nickel. Examples of the shape of the anode current collector include a foil shape and a plate shape. The shape of the anode current collector in plan view is not particularly limited, and examples thereof include a circular shape, an elliptical shape, a rectangular shape, and an arbitrary polygonal shape. The thickness of the anode current collector varies depending on the shape, but may be, for example, in a range of 1 μm to 50 μm or in a range of 5 μm to 20 μm.

### Solid Electrolyte Layer

The solid electrolyte layer includes a solid electrolyte, and optionally includes a binder or the like.

The solid electrolyte layer may be a layer consisting of one layer, or may be a layer consisting of two layers: a first solid electrolyte layer and a second solid electrolyte layer.

Examples of the solid electrolyte include solid electrolytes that can be contained in the above-described cathode layer. Further, when two or more kinds of solid electrolytes are used, two or more kinds of solid electrolytes may be mixed, or two or more layers of each solid electrolyte may be formed to form a multilayer structure.

The proportion of the solid electrolyte in the solid electrolyte layer is not particularly limited, but may be, for example, 50% by mass or more and 99% by mass or less.

Examples of the binder include binders that can be contained in the cathode layer described above.

When the solid electrolyte layer contains a binder, the content of the binder may be 0% by mass to 10% by mass with respect to the total amount of the solid electrolyte layer.

The thickness of the solid electrolyte layer may be 10 μm or more from the viewpoint of suppressing a short circuit of the solid-state battery, or may be 100 μm or less from the viewpoint of reducing the resistance of the solid-state battery.

The solid electrolyte layer can be formed, for example, by the following method.

A solid electrolyte slurry containing a solid electrolyte, a binder, and a solvent may be prepared, and a solid electrolyte slurry may be applied on a release film to form a solid electrolyte layer.

Examples of the solvent include a solvent that can be used for preparing the above-described cathode slurry.

A manufacturing method a solid-state battery according to the present disclosure includes (1) a film forming step and (2) a pressing step.

### (1) Deposition Process

In the film forming step, one surface of the solid-electrolyte layer is used as a film forming face, and a protective layer having Li ionic conductivity is formed on the film forming face.
in the film forming, the protective layer is formed on the film forming face such that an area of the protective layer is smaller than an area of the solid electrolyte layer, when viewing the laminate from a side of the anode layer in plan view.

In the film forming step, when a laminate in which the anode layer, the protective layer, the solid electrolyte layer, and the cathode layer are stacked in this order is viewed from the side of the anode layer in plan view, the solid electrolyte layer may extend outward from all the outer edges of the protective layer.

In the film forming step, the film forming method is not particularly limited, and may be a vapor deposition method, ion plating, sputtering, chemical vapor deposition (CVD), or the like.

In the film forming step, the protective layer may be formed on the film forming face by sputtering from the viewpoint of being able to uniformly form the protective layer.

### (2) Press Process

In the pressing step, after the film forming step, a laminated body in which the anode layer, the protective layer, the solid electrolyte layer, and the cathode layer are laminated in this order is obtained, and the laminated body is pressed.

Examples of the cathode layer, the anode layer, and the solid electrolyte layer used in the pressing step include the same ones as those exemplified in the above-described solid-state battery.

The pressing pressure for pressing the laminate in the pressing step is not particularly limited, but may be less than or equal to 400 MPa, less than or equal to 392 MPa, or less than or equal to 300 MPa from the viewpoint of suppressing the short circuit of the solid-state batteries.

The pressing method is not particularly limited, and examples thereof include a cold isotropic press and a roll press.

Depending on the pressing in the pressing step, the solid electrolyte contained in the solid electrolyte layer is less likely to be deformed. Therefore, the solid electrolyte contained in the solid electrolyte layer after the pressing and the solid electrolyte contained in the solid electrolyte layer before the pressing can be regarded as the same.

### 2. Second Embodiment

In the present disclosure, a manufacturing method a solid-state battery includes a cathode layer, an anode layer, and a solid electrolyte layer disposed between the cathode layer and the anode layer, and using a deposition-dissolution reaction of metal lithium is provided.
film forming of a protective layer with Li-ionic conductivity on a film forming face of the solid electrolyte layer, in which one face of the solid electrolyte layer is the film forming face, and
following the film forming, laminating the anode layer, the protective layer, the solid electrolyte layer, and the cathode layer, to obtain a laminate that is laminated in this order, and pressing the laminate, in which
the solid electrolyte layer includes a first solid electrolyte layer and a second solid electrolyte layer, and

In the film forming step, one surface of the first solid electrolyte layer is the film forming face. A manufacturing method a solid-state battery is provided in which, after the protective layer is formed on the film forming face, the second solid electrolyte layer is laminated and pressed on a surface of the first solid electrolyte layer opposite to the film forming face to obtain the solid electrolyte layer.

When the solid electrolyte layer includes the first solid electrolyte layer and the second solid electrolyte layer, one surface of the first solid electrolyte layer is defined as a film formation surface in the film formation step. After the protective layer is formed on the film forming face, the second solid electrolyte layer may be laminated and pressed on the surface of the first solid electrolyte layer opposite to the film forming face to obtain a solid electrolyte layer. The pressing method and the pressing pressure of the solid electrolyte layer may be the same as the pressing method and the pressing pressure of the laminate described above.

The solid electrolyte layer is formed into two layers, and after the introduction of the protective layer to the anode layer side of the solid electrolyte layer, the anode layer side of the solid electrolyte layer and the cathode layer side of the solid electrolyte layer are bonded to each other. Accordingly, even when the area of the protective layer is the same as the area of the solid electrolyte layer when the laminate is viewed from the anode layer side in plan view, the wraparound of the protective layer around the cathode layer side and the cathode layer of the solid electrolyte layer can be prevented. In the case of the second embodiment, the area of the laminated surface of the protective layer may be the same as or smaller than the area of the laminated surface of the solid electrolyte layer.

### Example 1

### Preparation of Cathode

NCA was used as the cathode active material. A sulfide solid electrolyte was used as the solid electrolyte.

Using butyl butyrate as a solvent, NCA and the binder and the conductive material were blended so as to have a mass-composition ratio of NCA:solid electrolyte:binder:conductive material=84.7:13.4:0.6:1.27 to prepare a cathode slurry.

Next, the obtained cathode slurry was coated on an aluminum foil as a cathode current collector with a coating gap of 225 μm.

Thereafter, the obtained coating film was temporarily dried at 60° C. for a predetermined time, dried at 165° C. for 1 hour, and a cathode having a basis weight 18.7 mg/cm² and a designed capacitance 3.0 mAh/cm² formed thereon was obtained.

### Preparation of Solid Electrolyte Layer

Particles of sulfide solid electrolyte with a mean particle diameter (D50) of 2.0 μm were used as the solid electrolyte.

Using butyl butyrate as a solvent, the sulfide solid electrolyte and the binder were blended so as to have a mass composition ratio of sulfide solid electrolyte:binder=92.6:7.4 to obtain a solid electrolyte slurry.

Next, a solid electrolyte slurry was coated on the release film with a coating gap of 325 μm. Thereafter, the obtained coating film was temporarily dried at room temperature for about 3 hours, and dried at 165° C. for 1 hour.

Two coated foils of diametric 14.5 mm were punched out from the dried coated foil, and the coated surfaces of the two coated foils were superimposed and pressed by a 7t. After the pressing, the release film was peeled off to obtain a self-supporting solid electrolyte layer.

### Preparation of Protective Layer

Sn as a protective layer was sputtered to a thickness of 0.1 μm on the self-supporting solid-electrolyte layer. In plan view, the area of the protective layer was smaller than the area of the solid electrolyte layer. When the area of the protective layer was made smaller than the area of the solid electrolyte layer, a mask of an appropriate size was applied to the solid electrolyte layer during sputtering.

### Preparation of the Anode

As the anode active material, a Mg foil having a thickness of 1.0 μm was used. As the anode current collector, a Ni foil was used. Mg foil and Ni foil were punched by diametrical 14.5 mm, and an anode layer made of a Mg foil was formed on the anode current collector, thereby obtaining an anode having an anode layer formed on the anode current collector.

### Preparation of Solid-State Battery

The prepared cathode is punched out with a diameter 11.28 mm, and self-supporting solid-electrolyte layers of the prepared diameter 14.5 mm are disposed between the cathode and the prepared anode to obtain a laminate. Al was used as the cathode terminal, and Ni was used as the anode terminal, and the laminated body was vacuum-sealed in an exterior body formed of a laminated film to which the cathode terminal and the anode terminal were attached, thereby obtaining a cell. Sealed cells were isotropically pressed with 392 MPa using CIP (cold isotropic pressing) to produce laminated cells, which are solid-state batteries.

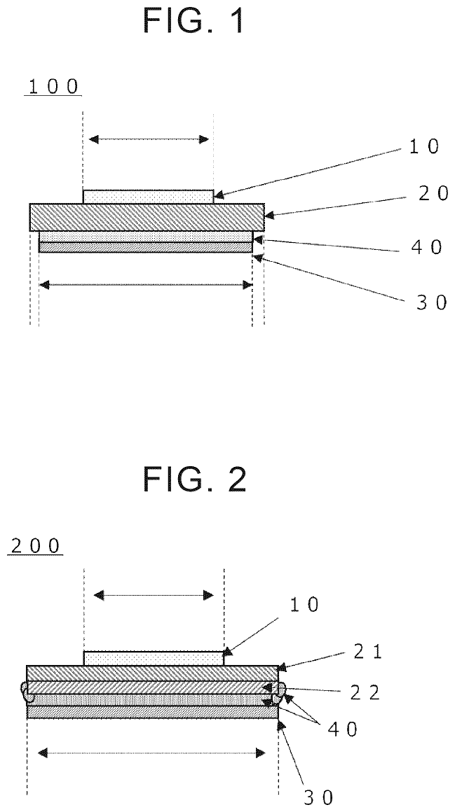

FIG. 1 is a schematic cross-sectional view showing a part of a solid-state battery of Example 1.

The solid-state battery 100 includes a cathode layer 10, a solid electrolyte layer 20, and an anode layer 30, and includes a protective layer 40 between the solid electrolyte layer 20 and the anode layer 30. In FIG. 1, a cathode current collector, an anode current collector, a cathode terminal, an anode terminal, and a laminate film are omitted for convenience.

In Example 1, the area of the laminated surface of the cathode layer 10 is smaller than the area of the laminated surface of the solid electrolyte layer 20, and the area of the laminated surface of the anode layer 30 is smaller than the area of the laminated surface of the solid electrolyte layer 20. The area of the laminated surface of the cathode layer 10 is smaller than the area of the laminated surface of the anode layer 30, and the area of the laminated surface of the protective layer 40 is smaller than the area of the laminated surface of the solid electrolyte layer 20.

Since the area of the laminated surface of the protective layer 40 is smaller than the area of the laminated surface of the solid electrolyte layer 20, it is possible to prevent the protective layer 40 from being circulated to the cathode layer 10 and to suppress a short circuit.

### Example 2

In the preparation of the solid-electrolyte layers, two coated foils of diametric 14.5 mm are punched out from the dried coated foil, and the release films of the two coated foils are peeled off. One is a first solid electrolyte layer, the other is a second solid electrolyte layer, and one surface of the first solid electrolyte layer is a film forming face. After Sn is sputtered with a thickness of 0.1 μm as a protective layer on the film forming face, a second solid electrolyte layer is laminated on the surface of the first solid electrolyte layer opposite to the film forming face and pressed by 7t to obtain a solid electrolyte layer having a protective layer on the surface of the first solid electrolyte layer side. Except for this, a solid-state battery was prepared in the same manner as in Example 1.

FIG. 2 is a schematic cross-sectional view showing a part of the solid-state battery of Example 2. In FIG. 2, a cathode current collector, an anode current collector, a cathode terminal, an anode terminal, and a laminate film are omitted for convenience.

The solid-state battery 200 includes a cathode layer 10, a second solid electrolyte layer 22, a first solid electrolyte layer 21, and an anode layer 30, and includes a protective layer 40 between the first solid electrolyte layer 21 and the anode layer 30.

After the solid electrolyte layer is formed into two layers and the protective layer 40 is introduced into the first solid electrolyte layer 21, the first solid electrolyte layer 21 and the second solid electrolyte layer 22 are bonded to each other. This prevents the protective layer 40 from wrapping around the second solid electrolyte layer 22 and the cathode layer 10. A short circuit could be suppressed.

### Example 3

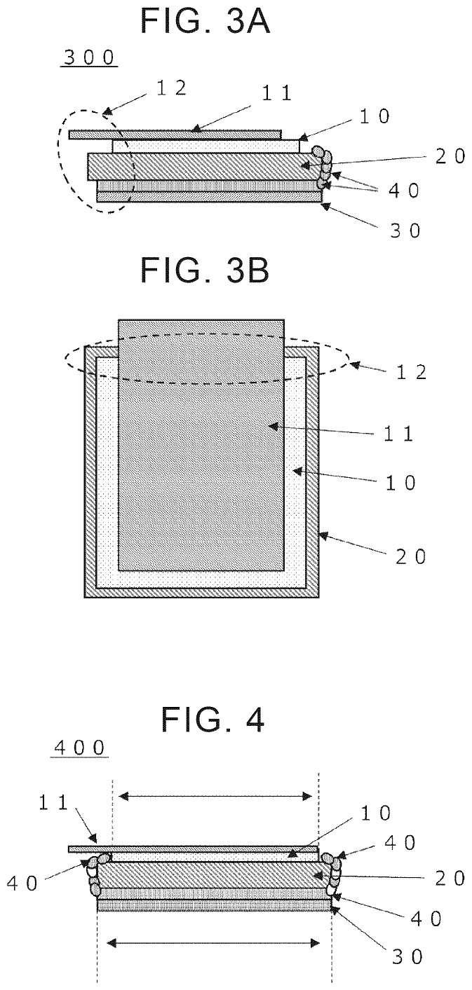

In the production of the protective layer, a solid-state battery was produced in the same manner as in Example 1, except that, in plan view, the protective layer was formed by sputtering so that the solid electrolyte layer extended outward from the outer edge of the protective layer only in the region of the side where the cathode terminal was present. FIG. 3A is a schematic cross-sectional view showing a part of a solid-state battery according to a third embodiment, and FIG. 3B is a schematic plan view of showing a part of a solid-state battery according to a third embodiment. In FIG. 3A and FIG. 3B, the same components as those in FIG. 1 are denoted by the same reference numerals, and the explanation thereof is omitted.

The solid-state battery 300 has a rectangular shape in plan view, and the solid electrolyte layer 20 extends outward from the outer edge of the protective layer 40 only in the region 12 of the side where the cathode terminal 11 is present. As a result, the protective layer 40 can be prevented from being circulated to the cathode terminal 11, and a short circuit can be suppressed.

### Comparative Example 1

In the production of the protective layer, a solid-state battery was produced in the same manner as in Example 1, except that the area of the protective layer was made the same as the area of the solid electrolyte layer in plan view.

FIG. 4 is a schematic cross-sectional view showing a part of the solid-state battery of Comparative Example 1. In FIG. 4, the same components as those in FIG. 1 are denoted by the same reference numerals, and description thereof will be omitted.

In the solid-state battery 400, the area of the laminated surface of the anode layer 30 is the same as the area of the laminated surface of the solid electrolyte layer 20, and the area of the laminated surface of the protective layer 40 is the same as the area of the laminated surface of the solid electrolyte layer 20.

Since the area of the laminated surface of the protective layer 40 is the same as the area of the laminated surface of the solid electrolyte layer 20, the protective layer 40 wraps around the cathode layer 10, comes into contact with the cathode terminal 11, and is short-circuited.

From the above, it can be seen that according to the present disclosure, a short circuit of a solid-state battery can be suppressed.

What is claimed is:

1. A manufacturing method of a solid-state battery that includes a cathode layer, an anode layer, and a solid electrolyte layer disposed between the cathode layer and the anode layer, and that also uses a deposition-dissolution reaction of metal lithium, the manufacturing method comprising:
film forming of a protective layer with Li-ionic conductivity on a film forming face of the solid electrolyte layer, in which one face of the solid electrolyte layer is the film forming face; and
following the film forming, laminating the anode layer, the protective layer, the solid electrolyte layer, and the cathode layer, to obtain a laminate that is laminated in this order, and pressing the laminate, wherein, in the film forming, the protective layer is formed on the film forming face such that an area of the protective layer is smaller than an area of the solid electrolyte layer, when viewing the laminate from a side of the anode layer in plan view.

2. The manufacturing method according to claim 1, wherein in the film forming, the solid electrolyte layer extends outward from all outer edges of the protective layer when viewing the laminate from the side of the anode layer in plan view.

3. The manufacturing method according to claim 1, wherein in the film forming, the protective layer is formed on the film forming face by sputtering.

4. The manufacturing method according to claim 1, wherein the protective layer includes at least one of an In element and a Sn element.

5. A manufacturing method of a solid-state battery that includes a cathode layer, an anode layer, and a solid electrolyte layer disposed between the cathode layer and the anode layer, and that also uses a deposition-dissolution reaction of metal lithium, the manufacturing method comprising:
film forming of a protective layer with Li-ionic conductivity on a film forming face of the solid electrolyte layer, in which one face of the solid electrolyte layer is the film forming face; and
following the film forming, laminating the anode layer, the protective layer, the solid electrolyte layer, and the cathode layer, to obtain a laminate that is laminated in this order, and pressing the laminate, wherein:
the solid electrolyte layer includes a first solid electrolyte layer and a second solid electrolyte layer; and
in the film forming, one face of the first solid electrolyte layer is taken as the film forming face and the protective layer is formed on the film forming face, following which the second solid electrolyte layer is laminated on a face of the first solid electrolyte layer opposite to the film forming face, and pressed, to obtain the solid electrolyte layer.
